(19) United States
(12) Patent Application Publication
(10) Pub. No.: US 2012/0276405 A1
(43) Pub. Date: Nov. 1, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); LONE-WEN TAI, Tu-Cheng (TW); SHUN-MAO LIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/217,930

(22) Filed: Aug. 25, 2011

(30) Foreign Application Priority Data
Apr. 27, 2011 (CN) 201110106784.2

(51) Int. Cl. B32B 15/01; C23C 14/35; C23C 14/16; B32B 15/04; B32B 3/00

(52) U.S. Cl. 428/615; 428/457; 428/336; 204/192.1; 204/192.15

(57) ABSTRACT

A coated article is described. The coated article includes a substrate and an alloy layer formed on the substrate. The alloy layer contains iron, silicon, boron, and carbon. The iron within the alloy layer has an atomic percentage of about 60%-95%, the silicon has an atomic percentage of about 1%-20%, the boron has an atomic percentage of about 1%-10%, and the carbon has an atomic percentage of about 1%-10%. A method for making the coated article is also described.

### CROSS-REFERENCE TO RELATED APPLICATIONS

This application is one of the two related co-pending U.S. patent applications listed below. All listed applications have the same assignee. The disclosure of each of the listed applications is incorporated by reference into the other listed application.

| Attorney | | |
|---|---|---|
| Docket No. | Title | Inventors |
| US 39200 | COATED ARTICLE AND METHOD FOR | HSIN-PEI |
| | MAKING THE SAME | CHANG |
| | | et al. |
| US 39202 | COATED ARTICLE AND METHOD FOR | HSIN-PEI |
| | MAKING THE SAME | CHANG |
| | | et al. |

### BACKGROUND

1. Technical Field

The present disclosure relates to a coated article and a method for making the coated article.

2. Description of Related Art

Physical vapor deposition (PVD) processes are widely used to form hard layers on low rigidity metal substrates. The hard layers are usually transition metal nitride layers or transition metal carbide layers which have high hardness and good chemical stability. However, the transition metal nitride layers or transition metal carbide layers can be highly fragile, with high residual stress, and are weakly bonded to the metal substrates, thus the transition metal nitride layers or transition metal carbide layers are prone to fall off the metal substrates during using.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overhead view of an exemplary embodiment of a vacuum sputtering device.

### DETAILED DESCRIPTION

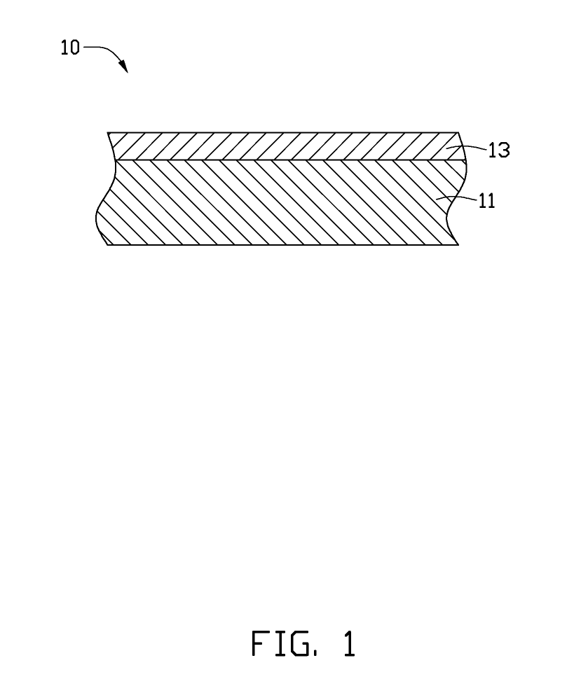

FIG. 1 shows a coated article 10 according to an exemplary embodiment. The coated article 10 includes a substrate 11, and an alloy layer 13 formed on a surface of the substrate 11.

The substrate 11 may be made of stainless or copper alloys, but is not limited to stainless or copper alloys.

The alloy layer 13 contains iron (Fe), silicon (Si), boron (B), and carbon (C). The atomic percentage of iron within the alloy layer 13 may be about 60%-95%. The atomic percentage of silicon within the alloy layer 13 may be about 1%-20%. The atomic percentage of boron within the alloy layer 13 may be about 1%-10%. The atomic percentage of carbon within the alloy layer 13 may be about 1%-10%. The alloy layer 13 may be formed by vacuum sputtering. The alloy layer 13 has a thickness of about 50 nm-100 nm and a high hardness.

A method for making the coated article 10 may include the following steps:

The substrate 11 is provided. The substrate 11 may be made of stainless steel or copper alloys, but is not limited to stainless steel or copper alloys.

The substrate 11 is cleaned using a degreasing solution and then rinsed in water and finally dried.

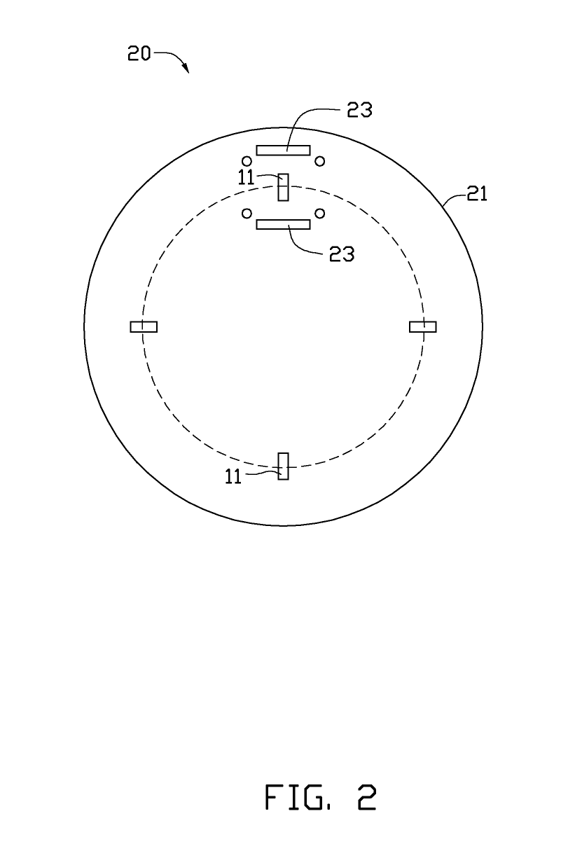

The alloy layer 13 may be magnetron sputtered on the cleaned substrate 11. Referring to FIG. 2, the substrate 11 may be positioned in a coating chamber 21 of a vacuum sputtering device 20. The coating chamber 21 is fixed with alloy targets 23.

Each alloy target 23 contains iron (Fe), silicon (Si), boron (B), and carbon (C). The atomic percentage of iron within the alloy target 13 may be about 60%-95%. The atomic percentage of silicon within the alloy target 13 may be about 1%-20%. The atomic percentage of boron within the alloy target 13 may be about 1%-10%. The atomic percentage of carbon within the alloy target 13 may be about 1%-10%. The alloy targets 23 may be formed by a method as follows:

Iron, silicon, boron, and carbon may be used as raw materials for the alloy targets 23. The atomic percentages of iron, silicon, boron, and carbon within the raw materials may be respectively about 60%-95%, 1%-20%, 1%-10%, and 1% - 10%. The raw materials may be positioned in a water jacketed copper crucible and are electric arc smelted at about 2000° C.-2500° C. to form an alloy body, or the raw materials may be positioned in a quartz crucible and are high frequency induction heating smelted at about 1800° C.-2000° C. to form an alloy body. The alloy body is then machined to form the alloy targets 23.

The coating chamber 21 is evacuated to about 8.0×10⁻³ Pa. Argon (Ar) gas having a purity of about 99.999% may be used as a working gas and is fed into the coating chamber 21 at a flow rate of about 150 standard-state cubic centimeters per minute (sccm) to about 300 sccm. The inside of the coating chamber 21 and the substrate 11 may be heated to about 100° C.-180° C. A power of about 10 kilowatt (kW)-15 kW is applied on the alloy targets 23, and alloy atoms are sputtered off from the alloy targets 23 to be deposited on the substrate 11 and form the alloy layer 13. During the depositing process, the substrate 11 may have a bias voltage of about −100 V to about −150 V. Depositing of the alloy layer 13 may take about 40 min-70 min. The alloy layer 13 has a thickness of about 50 nm-100 nm.

The alloy layer 13 has a high hardness. This is because the silicon, boron, carbon, together with the iron within the alloy layer 13 enable the alloy layer 13 a distorted crystal lattice structure, the distorted crystal lattice structure effectively resists the crystalline dislocation movement in the alloy layer 13 and thus enhances the strength of the alloy layer 13. Additionally, the silicon, boron, and carbon mostly form covalent bonds with the iron in the alloy layer 13, the covalent bonds further provides the alloy layer 13 a high hardness. Furthermore, the alloy layer 13 is securely bonded to the substrate 11, and has a low fragility, and a low residual stress.

Specific examples of making the coated article 10 are described as follows. The process of cleaning the substrate 11 in these specific examples may be substantially the same as previously described so it is not described here again. Additionally, the magnetron sputtering process of forming the alloy layer 13 in the specific examples are substantially the same as described above, and the specific examples mainly emphasize the different process parameters of making the coated article 10.

### Example 1

The substrate 11 is made of stainless steel.

Forming the alloy targets 23: iron, silicon, boron, and carbon are used as raw materials for the alloy targets 23. The atomic percentages of the iron, silicon, boron, and carbon in the raw materials are respectively 70%, 15%, 10%, and 5%. The raw materials are positioned in a water jacketed copper crucible and are electric arc smelted at about 2500° C. to form an alloy body. The alloy body is then machined to form the alloy targets 23.

Sputtering to form the alloy layer 13 on the substrate 11: the flow rate of argon gas is 150 sccm; the substrate 11 has a bias voltage of −100 V; the alloy targets 23 are applied with a power of 15 kW; the temperature of the substrate 11 is 100° C.; sputtering of the alloy layer 13 takes 40 min; the alloy layer 13 has a thickness of 50 nm.

### Example 2

The substrate 11 is made of copper alloy.

Forming the alloy targets 23: iron, silicon, boron, and carbon are used as raw materials for the alloy targets 23. The atomic percentages of the iron, silicon, boron, and carbon in the raw materials are respectively 90%, 5%, 4%, and 1%. The raw materials are positioned in a quartz crucible and are high frequency induction heating smelted at about 2000° C. to form an alloy body. The alloy body is then machined to form the alloy targets 23.

Sputtering to form the alloy layer 13 on the substrate 11: the flow rate of argon gas is 300 sccm; the substrate 11 has a bias voltage of −150 V; the alloy targets 23 are applied with a power of 10 kW; the temperature of the substrate 11 is 180° C.; sputtering of the alloy layer 13 takes 60 min; the alloy layer 13 has a thickness of 100 nm.

The hardness of the alloy layers 13 described in the above examples 1-2 has been tested according to an American Society for Testing Materials (ASTM) standard. The test indicated that the pencil hardness of the alloy layers 13 was more then 9 H. Thus, the coated article 10 has an excellent hardness.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A coated article, comprising:
a substrate; and
an alloy layer formed on the substrate, the alloy layer containing iron, silicon, boron, and carbon, the iron within the alloy layer having an atomic percentage of about 60% - 95%, the silicon having an atomic percentage of about 1%-20%, the boron having an atomic percentage of about 1%-10%, and the carbon having an atomic percentage of about 1%-10%, wherein the silicon, the boron, and the carbon are all covalently bonded with the iron in the alloy layer.

2. The coated article as claimed in claim 1, wherein the substrate is made of stainless steel or copper alloys.

3. The coated article as claimed in claim 1, wherein the alloy layer has a thickness of about 50 nm-100 nm.

4. (canceled)

5. The coated article as claimed in claim 1, wherein the alloy layer has a pencil hardness of more than 9 H.

6. A method for making a coated article, comprising:
providing a substrate;
forming an alloy target containing iron, silicon, boron, and carbon; and
forming an alloy layer on the substrate by vacuum sputtering using the alloy target, the alloy layer containing iron, silicon, boron, and carbon, the iron within the alloy layer having an atomic percentage of about 60%-95%, the silicon having an atomic percentage of about 1%-20%, the boron having an atomic percentage of about 1%-10%, and the carbon having an atomic percentage of about 1%-10%.

7. The method as claimed in claim 6, wherein forming the alloy target uses iron, silicon, boron, and carbon as raw materials, the iron, silicon, boron, and carbon in the raw materials have atomic percentages of respectively 60%-95%, 1% -20%, 1%-10%, and 1%-10%.

8. The method as claimed in claim 7, wherein forming the alloy target is carried out by positioning the raw materials in a water jacketed copper crucible and electric arc smelting the raw materials at about 2000° C.-2500° C., or positioning the raw material in a quartz crucible and high frequency induction heating smelting the raw materials at about 1800° C.-2000° C.

9. The method as claimed in claim 6, wherein forming the alloy layer uses a magnetron sputtering process; uses argon as a working gas, the argon having a flow rate of about 150 sccm-300 sccm; the alloy target is applied with a power of about 10 kW-15 kW; the substrate has a temperature of about 100° C.-180° C., magnetron sputtering of the alloy layer takes about 40 min-70 min.

10. The method as claimed in claim 9, wherein the substrate has a bias voltage of about −100 V to about −150 V during sputtering of the alloy layer.

11. The method as claimed in claim 6, further comprising a step of cleaning the substrate before forming the alloy layer.

12. The method as claimed in claim 6, wherein the substrate is made of stainless steel or copper alloys.

13. The method as claimed in claim 6, wherein the alloy layer has a thickness of about 50 nm-100 nm.
